(19) United States
(12) Patent Application Publication
(10) Pub. No.: US 2023/0312983 A1
(43) Pub. Date: Oct. 5, 2023

(54) POLISHING COMPOSITION, AND POLISHING METHOD USING POLISHING COMPOSITION

(71) Applicant: YAMAGUCHI SEIKEN KOGYO CO., LTD., Aichi (JP)

(72) Inventors: Yuji GOTO, Aichi (JP); Sanaki HORIMOTO, Aichi (JP); Tetsuro HARAGUCHI, Aichi (JP); Akira SUGAWA, Aichi (JP)

(73) Assignee: YAMAGUCHI SEIKEN KOGYO CO., LTD., Aichi (JP)

(21) Appl. No.: 18/018,093

(22) PCT Filed: Jul. 9, 2021
(86) PCT No.: PCT/JP2021/026023

§ 371 Date: Jun. 14, 2023

(30) Foreign Application Priority Data
Jul. 27, 2020 (JP) 2020-126340
Dec. 17, 2020 (JP) 2020-208968

(51) Int. Cl. C09G 1/16

(52) U.S. Cl. CPC C09G 1/16

(57) ABSTRACT

Provided is a polishing composition capable of speeding up a mirror polishing in terms of polishing rate and the like, improving the smoothness and the flatness of a wafer surface of a semiconductor wafer after the mirror polishing, enabling mirror finishing with high processing accuracy, and having excellent storage stability.

The polishing composition is for polishing a polishing target including a group III-V compound as a constituent component, and includes colloidal silica, an oxidizing agent, an oxidation accelerator for accelerating the oxidation reaction on the surface of the polishing target by the oxidizing agent, a stabilizer for controlling the accelerating action of the oxidation reaction on the surface of the polishing target by the oxidation accelerator, and water.

### CROSS REFERENCE TO RELATED APPLICATIONS

This application claims the benefit of and priority to PCT Patent Application No. PCT/JP2021/026023, filed on Jul. 9, 2021, which claims the benefit of and priority to Japanese Patent Application Nos. JP-2020-126340, filed on Jul. 27, 2020, and JP-2020-208968, filed on Dec. 17, 2020, both with the Japanese Patent Office, the entire contents of which are incorporated herein by reference.

### BACKGROUND OF THE INVENTION

### Technical Field

The present invention relates to a polishing composition and a polishing method using the polishing composition. More specifically, the present invention relates to a polishing composition used for mirror polishing a wafer surface of a compound semiconductor wafer which is a polishing target containing a group III-V compound such as gallium arsenide (GaAs), indium phosphide (InP), gallium phosphide (GaP), and gallium nitride (GaN) as a constituent component, and a polishing method using the polishing composition.

### Description of Related Art

Conventionally, as a substrate and an element of various semiconductor devices such as a semiconductor laser, a light emitting diode, a light modulation element, a light detecting element, and a solar cell, a compound semiconductor wafer (hereinafter, simply referred to as “a semiconductor wafer”) containing a group III-V compound such as GaAs, InP, GaP, and GaN as a constituent component has been frequently used, and especially in recent years, the demand for the semiconductor wafer has been greatly increased because of the popularization of various electronic devices and the like.

A semiconductor wafer is generally manufactured by slicing a single crystal obtained by crystal growing a group III-V compound, lapping, and performing various processing steps such as etching and polishing, followed by final polishing to finish the semiconductor wafer.

The final polishing corresponding to the final step (finishing step) of the semiconductor wafer is a step for smoothing the wafer surface of the semiconductor wafer and finishing to a mirror surface. For example, a polishing pad is mounted on a rotatable circular surface plate, and the polishing pad is rotated while the semiconductor wafer before polishing is pressed against the pad surface (polishing surface) of the polishing pad while the polishing liquid prepared in advance is dropped onto the pad surface, whereby the wafer surface is polished by chemical action and mechanical action.

The polishing of the semiconductor wafer described above is conventionally performed by two steps of primary polishing (rough polishing) and secondary polishing (mirror finish polishing). For example, a polishing method in which, at the time of primary polishing of a semiconductor wafer, polishing using abrasive grains having a large particle size is performed first and then polishing using abrasive grains having a small particle size is performed (see Patent Document 1), a polishing method in which a polishing agent having a characteristic in the particle shape and the particle size distribution of the abrasive grains is used, and in particular, sodium dichloroisocyanurate is used as an oxidizing agent (see Patent Document 2), a polishing method in which, at the time of primary polishing of a GaAs wafer, a polishing liquid having a different composition is used in pre-polishing and post-polishing (see Patent Document 3), and the like are known. As described above, various methods have been employed to accurately mirror finishing the wafer surface of the semiconductor wafer.

In particular, after the processing of mirror polishing on the semiconductor wafer, a layer is further formed by epitaxial growth on the mirror surface. Therefore, the processing accuracy (finishing accuracy) of mirror polishing by the final polishing is extremely important, and it is required to form a wafer surface having excellent smoothness and flatness with little unevenness, small waviness, and small surface abnormality such as pits.

[Patent Document 1] JP 2002-18705 JP
[Patent Document 2] JP 2005-264057 JP
[Patent Document 3] JP 2008-198724 JP

### SUMMARY OF THE INVENTION

However, the polishing method and the polishing liquid (polishing composition) to be used of Patent Documents 1 to 3 described above are difficult to speed up the polishing process because a long processing time is required, or may not be possible to sufficiently satisfy the required processing accuracy of mirror polishing. In addition, the use of sodium dichloroisocyanurate as an oxidizing agent disclosed in Patent Documents 2 and 3 has a large impact on the storage stability of the polishing liquid itself, and has a problem that the polishing rate tends to decrease with time, making it difficult to use the polishing liquid over a long period of time.

In view of the above circumstances, it is an object of the present invention to provide a polishing composition capable of speeding up a mirror polishing in terms of polishing rate and the like, improving the smoothness and the flatness of a wafer surface of a semiconductor wafer after the mirror polishing, enabling mirror finishing with high processing accuracy, and having excellent storage stability, and to provide a polishing method using the polishing composition.

As a result of extensive studies to solve the above problems, the present inventors have found that by polishing using a polishing composition prepared to contain a specific component, speeding up of the mirror polishing of a semiconductor wafer can be achieved, and the present invention described below has been completed.

[1] A polishing composition for polishing a polishing target containing a group III-V compound as a constituent component, comprising: colloidal silica; an oxidizing agent; an oxidation accelerator for accelerating an oxidation reaction on a surface of the polishing target by the oxidizing agent; a stabilizer for controlling an accelerating action of the oxidation reaction on a surface of the polishing target by the oxidation accelerator; and water.

[2] The polishing composition according to [1], wherein the group III-V compound is at least one or more selected from the group consisting of gallium arsenide, gallium phosphide, indium phosphide, indium arsenide, aluminum arsenide, indium gallium arsenic compounds, indium gallium phosphorus compounds, aluminum gallium arsenic compounds, indium aluminum gallium arsenic compounds, gallium nitride, gallium antimony compounds, and indium antimony compounds.

[3] The polishing composition according to [1] or [2], wherein the oxidizing agent is peroxide, permanganic acid or a salt thereof, chromic acid or a salt thereof, peroxo acid or a salt thereof, halogen oxo acid or a salt thereof, oxygen acid or a salt thereof, and a mixture thereof.

[4] The polishing composition according to any one of [1] to [3], wherein the oxidizing agent is hydrogen peroxide.

[5] The polishing composition according to any one of [1] to [4], wherein the oxidation accelerator is either an inorganic acid metal salt or an organic acid metal salt.

[6] The polishing composition according to [5], wherein the inorganic acid metal salt is either iron nitrate or iron sulfate.

[7] The polishing composition according to any one of [1] to [6], wherein the stabilizer is at least one or more selected from the group consisting of phosphoric acid, phosphorous acid, organic phosphonic acid, polycarboxylic acid, and polyaminocarboxylic acid.

[8] The polishing composition according to [7], wherein the polycarboxylic acid is either malonic acid or citric acid.

[9] The polishing composition according to any one of [1] to [8], wherein a pH value at 25° C. is in a range of 0.1 to 6.0.

[10] A polishing method using the polishing composition according to any one of [1] to [9] to polish a polishing target containing a group III-V compound as a constituent component.

The polishing composition of the present invention is characterized in that it contains an oxidizing agent, an oxidation accelerator, and a stabilizer, and by the polishing method using the polishing composition of the present invention for polishing a semiconductor wafer using such a polishing composition, mirror polishing excellent in flatness and smoothness at a high polishing rate can be achieved. Furthermore, an effect of excellent long-term storage stability of the polishing composition can also be obtained.

### DETAILED DESCRIPTION OF THE INVENTION

Embodiments of the present invention will be described below. The present invention is not limited to the following embodiments, but can be changed, modified, and improved without departing from the scope of the invention.

### 1. Polishing Composition

A polishing composition according to an embodiment of the present invention contains colloidal silica, an oxidizing agent, an oxidation accelerator, a stabilizer, and water, and the materials used are prepared according to a predetermined blending ratio. Although the polishing composition of the present embodiment is excellent in storage stability, the polishing composition is preferably used for polishing a semiconductor wafer such as a GaAs wafer, an InP wafer, a GaP wafer, and a GaN wafer promptly after preparation as the polishing composition, for example, it is preferably used for polishing within 48 hours from preparation, and more preferably used for polishing within 24 hours from preparation of the polishing composition.

### 1.1 Colloidal Silica

The colloidal silica used as the material in the polishing composition of the present embodiment preferably has an average particle size (D50) in the range of 10 to 200 nm, and more preferably has an average particle size (D50) of 20 to 100 nm. When the average particle size (D50) of the colloidal silica is less than 10 nm, the polishing resistance between the substrate and the polishing pad at the time of polishing increases, and the polishing may not proceed smoothly. When the average particle size (D50) of the colloidal silica exceeds 200 nm, scratches may occur in the substrate. The average particle size (D50) of the colloidal silica is calculated by analyzing the colloidal silica based on an observation result by a transmission electron microscope (TEM) (details will be described later).

The colloidal silica is known to have shapes such as a spherical shape, a kompeito-typed shape (like particles having convexes on the surface), and a heteromorphic shape, and is in a colloidal state that primary particles are mono-dispersed in water. The colloidal silica of various shapes can be used as a material of the polishing composition of the present embodiment.

The colloidal silica used as a material can be manufactured by a conventionally known manufacturing process, for example, a water glass process in which an alkali metal silicate such as sodium silicate or potassium silicate is used as a raw material, and the raw material is subjected to a condensation reaction in an aqueous solution to grow particles of colloidal silica; an alkoxysilane process in which a tetraalkoxysilane such as tetraethoxysilane is used as a raw material, and the raw material is subjected to a condensation reaction by hydrolysis with an acid or an alkali in a solvent containing a watersoluble organic solvent such as alcohol to grow particles of colloidal silica, or a process in which colloidal silica is synthesized by reacting metallic silicon and water in the presence of an alkali catalyst. In view of the manufacturing cost, the water glass process can be suitably used. The colloidal silica as a material used in the polishing composition of the present embodiment can be manufactured by using these synthesis processes and the like as appropriate.

In the polishing composition of the present embodiment, the content (content rate) of the colloidal silica contained in the polishing composition is preferably in the range of 1 to 50% by mass, and more preferably 2 to 40% by mass. When the content of the colloidal silica is less than 1% by mass, the polishing resistance between the substrate and the polishing pad at the time of polishing increases, and the polishing may not proceed smoothly. When the content of the colloidal silica exceeds 50% by mass, the colloidal silica may be easily gelled.

### 1.2 Oxidizing Agent

As the oxidizing agent used as the material in the polishing composition of the present embodiment, peroxide, permanganic acid or a salt thereof, chromic acid or a salt thereof, peroxoacid or a salt thereof, halogenoxoacid or a salt thereof, oxygen acid or a salt thereof, and a mixture of two or more of these can be used.

More specifically, hydrogen peroxide, sodium peroxide, barium peroxide, potassium peroxide, potassium permanganate, metal salts of chromic acid, metal salts of dichromic acid, persulfuric acid, sodium persulfate, potassium persulfate, ammonium persulfate, peroxophosphoric acid, sodium peroxoborate, performic acid, peracetic acid, hypochlorous acid, sodium hypochlorite, calcium hypochlorite, and the like can be used. In particular, hydrogen peroxide, persulfuric acid and a salt thereof, and hypochlorous acid and a salt thereof are preferably used, more preferably hydrogen peroxide is used.

The oxidizing agent has a function of oxidizing the surface of a semiconductor wafer such as a GaAs wafer to form an oxidized layer, and has an action of facilitating the progress of polishing of a semiconductor wafer to be polished. Further, it has an effect of oxidizing polishing debris such as arsenic compounds that is generated during polishing of the semiconductor wafer and discharged, and also has a function of suppressing deterioration of the working environment.

In the polishing composition of the present embodiment, the content (content rate) of the oxidizing agent contained in the polishing composition is preferably in the range of 0.01 to 10.0% by mass, and more preferably 0.1 to 5.0% by mass. When the content of the oxidizing agent is less than 0.01% by mass, the polishing rate may decrease. When the content of the oxidizing agent exceeds 10.0% by mass, the surface roughness of the substrate after polishing may deteriorate.

### 1.3 Oxidation Accelerator

As the oxidation accelerator used as the material of the polishing composition of the present embodiment, an inorganic acid metal salt or an organic acid metal salt can be used. In particular, an inorganic acid metal salt is preferably used.

More specifically, the inorganic acid metal salt may be an iron salt, a copper salt, a silver salt, and a manganese salt of nitric acid, sulfuric acid, hydrochloric acid, phosphoric acid, and the like. For example, iron (III) nitrate, iron (III) sulfate, iron (II) sulfate, iron (III) chloride, or iron (II) chloride is preferably used, and iron (III) nitrate is more preferably used. These inorganic acid metal salts can be used as either an anhydride or a hydrate.

Examples of the organic acid metal salt include a metal salt of polycarboxylic acid and a metal salt of polyaminocarboxylic acid. More specifically, examples of the metal salt of polycarboxylic acid include metal salts of oxalic acid, malonic acid, succinic acid, maleic acid, phthalic acid, and citric acid, and examples of the metal salt of polyaminocarboxylic acid include metal salts of ethylenediaminetetraacetic acid, diethylenetriaminepentaacetic acid, ethylenediaminediacetic acid, and triethylenetetraminehexaacetic acid. An iron salt, a copper salt, a silver salt, and a manganese salt of these organic acid can be used.

The oxidation accelerator has an effect of accelerating the oxidation reaction of the semiconductor wafer by the above-described oxidizing agent. Therefore, the polishing of the semiconductor wafer is facilitated.

In the polishing composition of the present embodiment, the content (content rate) of the oxidation accelerator contained in the polishing composition is preferably in the range of 0.01 to 10.0% by mass, and more preferably 0.02 to 5.0% by mass. When the content of the oxidation accelerator is less than 0.01% by mass, the polishing rate may decrease and the surface roughness of the substrate after polishing may deteriorate. When the content of the oxidation accelerator exceeds 10.0% by mass, the effect of the oxidation accelerator reaches the ceiling, which is economically disadvantageous.

### 1.4 Stabilizer

The stabilizer used as the material in the polishing composition of the present embodiment may be at least one selected from the group consisting of phosphoric acid, phosphorous acid, organic phosphonic acid, polycarboxylic acid, and polyaminocarboxylic acid. Specific examples of the polycarboxylic acid include oxalic acid, malonic acid, succinic acid, maleic acid, phthalic acid, and citric acid. Specific examples of the polyaminocarboxylic acid include ethylenediaminetetraacetic acid, diethylenetriaminepentaacetic acid, ethylenediaminediacetic acid, and triethylenetetraminehexaacetic acid. Alkali metal salts thereof may also be used.

On the other hand, specific examples of the organic phosphonic acid include 2-aminoethylphosphonic acid, 1-hydroxyethyliden-1,1-diphosphonic acid, aminotri(methylenephosphonic acid), ethylenediaminetetra(methylenephosphonic acid), diethylenetriaminepenta(methylenephosphonic acid), ethane-1,1-diphosphonic acid, ethane-1,1,2-triphosphonic acid, ethane-1-hydroxy-1,1,2-triphosphonic acid, ethane-1,2-dicarboxy-1,2-diphosphonic acid, methane hydroxyphosphonic acid, 2-phosphonobutan-1,2-dicarboxylic acid, 1-phosphonobutane-2,3,4-tricarboxylic acid, and α-methylphosphonosuccinic acid.

In the above, phosphoric acid, 1-hydroxyethylidene-1,1-diphosphonic acid, malonic acid, or citric acid is preferably used, and malonic acid or citric acid is more preferably used.

The stabilizer has an effect of controlling the accelerating action of the oxidation reaction of the semiconductor wafer by the oxidation accelerator. Thus, the progress of the oxidation reaction by the oxidizing agent and the oxidation accelerator can be controlled. Therefore, the oxidation reaction on the surface of the polishing target can slowly proceed after the preparation of the polishing composition. As a result, the effect of the polishing composition can be exhibited over a long period of time, and the storage stability of the polishing composition can be maintained. Thus, the polishing of the semiconductor wafer can be performed stably and smoothly over a long period of time.

In the polishing composition of the present embodiment, the content (content rate) of the stabilizer contained in the polishing composition is preferably in the range of 0.01 to 10.0% by mass, and more preferably 0.02 to 5.0% by mass. When the content of the stabilizer is less than 0.01% by mass, bubbles may be generated during preparation of the polishing composition, and the stability of the polishing composition with time may deteriorate. When the content of the stabilizer exceeds 10.0% by mass, the effect of the stabilizer reaches the ceiling, which is economically disadvantageous.

### 1.5 Water

Water used as the material of the polishing composition of the present embodiment is not particularly limited as long as it is pure water, ultrapure water, or distilled water from which ions and suspended matter have been removed.

### 1.6 Physical Property of the Polishing Composition

The pH value at 25° C. of the polishing composition of the present embodiment is preferably in the range of 0.1 to 6.0, and more preferably in the range of 0.5 to 5.0. The pH value of the polishing composition can be adjusted by the content ratio of the oxidation accelerator and the stabilizer. Furthermore, an acidic compound or a basic compound may be added as appropriate to adjust the pH value. When the pH value at 25° C. of the polishing composition is less than 0.1, corrosion of the polishing machine and peripheral devices may be likely to occur. When the pH value at 25° C. of the polishing composition exceeds 6.0, gelation of the colloidal silica may be likely to occur, and the surface roughness of the substrate after polishing may deteriorate.

### 2. Polishing Target

A semiconductor wafer as a polishing target to be polished by the polishing composition of the present embodiment contains a group III-V compound as a constituent component, and is obtained by thinly cutting gallium arsenide (GaAs) or indium phosphide (InP) described above. Further, the group III-V compound is selected from the group consisting of gallium phosphide (GaP), indium arsenide (InAs), aluminum arsenide (AlAs), indium gallium arsenic compound (InGaAs), indium gallium arsenide phosphorus compound (InGaAsP), aluminum gallium arsenic compound (AlGaAs), indium aluminum gallium arsenic compound (InAlGaAs), gallium nitride (GaN), gallium antimony compound (GaSb), and indium antimony compound (InSb). A semiconductor wafer (a group III-V compound semiconductor wafer) of the polishing target is formed containing at least one or more of these group III-V compounds as constituent components.

### 3. Polishing Method Using Polishing Composition

A polishing method using the polishing composition of one embodiment of the present invention (hereinafter, simply referred to as a “polishing method”), in which a semiconductor wafer containing a group III-V compound as a constituent component is polished as a polishing target using the polishing composition of the present embodiment, is performed. The polishing method includes two stages (steps) of primary polishing and secondary polishing performed after the primary polishing, both of which have chemical polishing and mechanical polishing properties.

The primary polishing in the polishing method is mainly for the purpose of speeding up the polishing rate and the like in the polishing process, in other words, improving the efficiency of the polishing process, and for the purpose of securing the flatness of the semiconductor wafer. Therefore, the primary polishing has a relatively high element of mechanical polishing. On the other hand, the secondary polishing in the polishing method is mainly for the purpose of final finishing in which the wafer surface of the semiconductor wafer is finished to a mirror surface, and the scratches, hazes, processing distortion, and the like on the wafer surface are removed to finish to a perfect mirror surface. Therefore, the secondary polishing has a relatively high element of chemical polishing.

In the secondary polishing, for the purpose of finishing to a perfect mirror surface, for example, a polishing pad having a two-layer structure including a base layer made of polyester fiber and a urethane foamed surface layer provided on the base layer is often used. Further, after the above-described secondary polishing, in order to remove adhering matter remaining on the wafer surface of the semiconductor wafer, and to remove the oxide film on the wafer surface, an etching process may be performed, and a film forming step of forming a film on the wafer surface by epitaxial growth may be performed. The polishing composition of the present embodiment can be used when the polishing method of the present embodiment is applied to a semiconductor wafer, and can be adopted at any stage (step) of the primary polishing and the secondary polishing described above.

In the above, a polishing pad having a two-layer structure including a base layer made of polyester fiber and a urethane foamed surface layer is used as an example of the polishing pad in the secondary polishing, but the present invention is not limited thereto, and a polishing pad made of a conventionally known nonwoven fabric, a foamed polyurethane, a porous resin, a non-porous resin, or the like can be appropriately selected and used. Further, the surface of the polishing pad may be grooved in a lattice, concentric, spiral, or the like, to facilitate the supply of the polishing composition to the polishing pad or to allow a certain amount of the polishing composition to remain in the polishing pad.

### EXAMPLES

Hereinafter, the present invention will be described in more detail based on examples, but the present invention is not limited to these examples. In addition, various modifications and improvements can be made to the present invention in addition to the following embodiments based on the knowledge of a person skilled in the art without departing from the spirit of the present invention.

### Preparation of Polishing Composition

Using the materials described in Table 1 below, the polishing compositions of Examples 1 to 17 and Comparative Examples 1 to 11 were prepared by mixing so as to contain the contents (% by mass) described in Table 1. The polishing compositions of Examples 1, 12, 14, and 16 were the same, the polishing compositions of Examples 4, 13, 15, and 17 were the same, the polishing compositions of Comparative Examples 1, 6, 8, and 10 were the same, and the polishing compositions of Comparative Examples 4, 7, 9, and 11 were the same. The polishing compositions of Examples 1 to 10, 12 to 17, and Comparative Examples 4, 7, 9, and 11 were subjected to polishing tests immediately after preparation as polishing compositions. On the other hand, in the polishing compositions of Comparative Examples 1 to 3, 6, 8, and 10, bubbles were generated after preparation as polishing compositions, and therefore, the polishing compositions were subjected to polishing tests after the generation of such bubbles had subsided. Further, the polishing composition of Example 11 was subjected to a polishing test after 2 hours have elapsed after preparation as a polishing composition, and in the polishing composition of Comparative Example 5, bubbles were generated after preparation as polishing compositions, and therefore, the polishing composition was subjected to the polishing test after 2 hours have elapsed after the generation of such bubbles had subsided.

The stabilizer was prepared so that the content was constant in % by mol in the polishing composition, and therefore, the content in % by mass in Tables 1 to 6 reflects the magnitude of each molecular weight. In Tables 1 and 2, HEDP represents 1-hydroxyethylidene-1,1-diphosphonic acid, EDTA represents ethylenediaminetetraacetic acid, and EDTA Fe represents ethylenediaminetetraacetic acid iron salt.

TABLE 1

| Materials used | | | Content in the polishing composition (% by mass) | Examples or Comparative Examples of Use |
|---|---|---|---|---|
| Colloidal silica | | Colloidal silica 1 average particle size (D50):23 nm | 2.5 | Examples 1 to 7, 9 to 17, and Comparative Examples 1 to 11 |
| | | | 5.0 | Example 8 |
| | | Colloidal silica 2 average particle size (D50):110 nm | 2.5 | Examples 1 to 7, 9 to 17, and Comparative Examples 1 to 11 |
| | | | 5.0 | Example 8 |
| Oxidizing agent | | Hydrogen peroxide | 0.6 | Examples 1 to 8, 10 to 17, and Comparative Examples 1 to 11 |
| | | | 1.2 | Example 9 |
| Oxidation accelerator | | Iron (III) nitrate nonahydrate | 0.1 | Examples 1 to 4, 8, 9, 11 to 17, Comparative Examples 1 to 3, 5, 6, 8, and 10 |
| | | | 0.3 | Example 10 |
| | | Iron (II) sulfate heptahydrate | 0.1 | Example 5 |
| | | Manganese (II) sulfate pentahydrate | 0.1 | Example 6 |
| | | EDTA Fe ²⁾ | 0.1 | Example 7 |
| Stabilizer¹) | Stabilizer used in Examples | Malonic acid | 0.14 | Examples 4 to 6, 8 to 11, 13, 15, 17, Comparative Examples 4, 7, 9, and 11 |
| | | Citric acid | 0.26 | Example 3 |
| | | Phosphoric acid | 0.13 | Examples 1, 12, 14, and 16 |
| | | HEDP ³⁾ | 0.29 | Example 2 |
| | | EDTA ⁴⁾ | 0.18 | Example 7 |
| | Additive used in Comparative Examples | Acetic acid | 0.08 | Comparative Example 3 |
| | | Nitric acid | 0.08 | Comparative Examples 2 and 5 |

1) Since the content of the stabilizer is constant in % by mol, the content in % by mass is a value reflecting the magnitude of each molecular weight.
2) EDTA Fe: Ethylenediaminetetraacetic acid iron salt
3) HEDP: 1-hydroxyethylidene-1,1-diphosphonic acid
4) EDTA: Ethylenediaminetetraacetic acid

### Particle Size of Colloidal Silica

The particle size (Heywood diameter) of the colloidal silica was measured as Heywood diameter (projected area equivalent circular diameter) by taking a photograph of a field of view at a magnification of 100,000 times using a transmission electron microscope (TEM) (manufactured by JEOL Ltd., transmission electron microscope JEM2000FX (200kV)) and analyzing the photograph using analysis software (manufactured by Mountech Co., Ltd., Mac-View Ver 4.0). The average particle size of the colloidal silica is the average particle size (D50) obtained by analyzing the particle size of about 2000 pieces of colloidal silica using the above-described method, and calculating the particle size at which the accumulated particle size distribution (based on accumulated volume) of 50% from the small particle size side using the above-described analysis software (manufactured by Mountech Co., Ltd., Mac-View Ver 4.0).

### (1) Polishing of GaAs Substrate

The polishing conditions for the polishing test of the polishing target using the polishing compositions prepared as Examples 1 to 11 and Comparative Examples 1 to 5 are as follows. The results of the polishing test under the polishing conditions are shown in Tables 2 and 3 below.

### Polishing Conditions of GaAs Substrate

Polishing apparatus: One-side polishing machine having surface plate diameter of 350 mm
Polishing target: 3-inch GaAs substrate
Polishing pad: Hard urethane IC1400 (grooved)
Polishing pressure: 200 g/cm²
Surface plate rotating speed: 60 rpm
Polishing time: 10 min
Feed rate of polishing composition: One-way feed, flow rate 40 ml/min

### Polishing Rate Ratio of GaAs Substrate

The weight of the 3-inch GaAs substrate which is a polishing target (hereinafter, simply referred to as “GaAs substrate”) was measured before and after the polishing test, and the polishing rate was calculated from the weight difference. The polishing rate ratio is shown as a relative value when the value of the polishing rate of Comparative Example 1 is 1 (reference). The larger the value of the polishing rate ratio, the higher the polishing rate, and the higher the productivity.

### State of Substrate Surface of GaAs Substrate

The surface of GaAs substrate after the polishing test was observed visually and with a scanning white-light interference microscope (manufactured by Hitachi High-Tech Science Corporation, VS-1540).

### Surface Roughness Sa of GaAs Substrate

The surface of GaAs substrate after the polishing test was subjected to measurement of surface roughness (Sa) at a measurement range of 102 µm×102 µm using the above-described scanning white-light interference microscope.

TABLE 2-1

| Experiment number | Colloidal silica (% by mass) | | Oxidizing agent | | Oxidation accelerator | | Stabilizer | | pH (25° C.) | Polishing rate ratio (Comparative Example 1=1) | Sa (nm) | State of substrate surface | Remarks |
|---|---|---|---|---|---|---|---|---|---|---|---|---|---|
| | D50= 23 nm | D50= 110 nm | Type | Amount added (% by mass) | Type | Amount added (% by mass) | Type | Amount added (% by mass) | | | | | |
| Example 1 | 2.5 | 2.5 | Hydrogen peroxide | 0.6 | Iron (III) nitrate | 0.1 | Phosphoric acid | 0.13 | 2.1 | 2.00 | 0.38 | Glossy | |
| Example 2 | 2.5 | 2.5 | Hydrogen peroxide | 0.6 | Iron (III) nitrate | 0.1 | HEDP | 0.29 | 2.1 | 2.13 | 0.34 | Glossy | |
| Example 3 | 2.5 | 2.5 | Hydrogen peroxide | 0.6 | Iron (III) nitrate | 0.1 | Citric acid | 0.26 | 2.0 | 2.50 | 0.35 | Glossy | |
| Example 4 | 2.5 | 2.5 | Hydrogen peroxide | 0.6 | Iron (III) nitrate | 0.1 | Malonic acid | 0.14 | 2.1 | 2.63 | 0.36 | Glossy | |
| Example 5 | 2.5 | 2.5 | Hydrogen peroxide | 0.6 | Iron (II) sulfate | 0.1 | Malonic acid | 0.14 | 2.3 | 2.88 | 0.37 | Glossy | |
| Example 6 | 2.5 | 2.5 | Hydrogen peroxide | 0.6 | Mn (II) sulfate | 0.1 | Malonic acid | 0.14 | 2.0 | 2.25 | 0.35 | Glossy | |
| Example 7 | 2.5 | 2.5 | Hydrogen peroxide | 0.6 | EDTA Fe ¹⁾ | 0.1 | EDTA²⁾ | 0.18 | 3.5 | 2.85 | 0.36 | Glossy | |
| Example 8 | 5.0 | 5.0 | Hydrogen peroxide | 0.6 | Iron (III) nitrate | 0.1 | Malonic acid | 0.14 | 2.3 | 2.75 | 0.37 | Glossy | |
| Example 9 | 2.5 | 2.5 | Hydrogen peroxide | 1.2 | Iron (III) nitrate | 0.1 | Malonic acid | 0.14 | 2.1 | 3.63 | 0.38 | Glossy | |

TABLE 2-2

| Experiment number | Colloidal silica (% by mass) | | Oxidizing agent | | Oxidation accelerator | | Stabilizer | | pH (25° C.) | Polishing rate ratio (Comparative Example 1=1) | Sa (nm) | State of substrate surface | Remarks |
|---|---|---|---|---|---|---|---|---|---|---|---|---|---|
| | D50= 23 nm | D50= 110 nm | Type | Amount added (% by mass) | Type | Amount added (% by mass) | Type | Amount added (% by mass) | | | | | |
| Example 10 | 2.5 | 2.5 | Hydrogen peroxide | 0.6 | Iron (III) nitrate | 0.3 | Malonic acid | 0.14 | 1.7 | 2.75 | 0.36 | Glossy | |
| Comparative Example 1 | 2.5 | 2.5 | Hydrogen peroxide | 0.6 | Iron (III) nitrate | 0.1 | - | - | 2.7 | 1 | 0.90 | With hazes on outer peripheral portion, With visible scratches | Generated a large amount of bubbles |
| Comparative Example 2 | 2.5 | 2.5 | Hydrogen peroxide | 0.6 | Iron (III) nitrate | 0.1 | Nitric acid | 0.08 | 1.6 | 1.75 | 0.34 | Glossy | Generated a large amount of bubbles |
| Comparative Example 3 | 2.5 | 2.5 | Hydrogen peroxide | 0.6 | Iron (III) nitrate | 0.1 | Acetic acid | 0.08 | 2.8 | 2.13 | 0.48 | Glossy, With visible scratches | Generated a small amount of bubbles |
| Comparative Example 4 | 2.5 | 2.5 | Hydrogen peroxide | 0.6 | - | - | Malonic acid | 0.14 | 2.1 | 1.88 | 66.50 | With hazes | |

1) EDTA Fe: Ethylenediaminetetraacetic acid iron salt
2) EDTA: Ethylenediaminetetraacetic acid

### Consideration of GaAs Substrate

As shown in Table 2, the polishing composition of Comparative Example 1 does not contain a stabilizer, which is an essential constituent component of the polishing composition of the present invention. Therefore, although a large amount of bubbles are generated immediately after the preparation of the polishing composition and it is difficult to handle the polishing composition in practical use, the above performance evaluation was performed on the polishing composition after the preparation. The polishing test itself was carried out after the generation of bubbles had subsided.

As shown in the results of Table 2 above, it is confirmed that the value of the polishing rate in the polishing composition of Comparative Example 1 was less than or equal to half the value of the polishing rates of the polishing compositions of Examples 1 to 4, and the value of surface roughness (Sa) of the substrate was significantly deteriorated as compared with the value of surface roughness (Sa) of the substrate in the polishing compositions of Examples 1 to 4. Further, although gloss was observed in the central portion of the substrate surface, hazes were generated in the outer peripheral portion of the substrate. In addition, several visible scratches were observed.

As shown in Table 2, the polishing composition of Comparative Example 2 used nitric acid instead of the stabilizer used in the polishing compositions of Examples 1 to 4, which are the polishing compositions of the present invention. Therefore, although a large amount of bubbles are generated immediately after the preparation of the polishing composition and it is difficult to handle the polishing composition in practical use, the above performance evaluation was performed on the polishing composition after the preparation. The polishing test itself was carried out after the generation of bubbles had subsided.

As shown in the results of Table 2 above, it is confirmed that the value of the polishing rate in the polishing composition of Comparative Example 2 was lower than the value of the polishing rates of the polishing compositions of Examples 1 to 4, while both the surface roughness of the substrate and the state of the substrate surface were good. As described above, since a large amount of bubbles were generated immediately after the preparation, the storage stability of the polishing composition was evaluated as follows. The results are shown in Table 3 below.

TABLE 3

| Experiment number | Colloidal silica (% by mass) | | Oxidizing agent | | Oxidation accelerator | | Stabilizer | | pH (25° C.) | Polishing rate ratio (Table 2 Comparative Example1=1) | Sa (nm) | State of substrate surface | Remarks |
|---|---|---|---|---|---|---|---|---|---|---|---|---|---|
| | D50= 23 nm | D50= 110 nm | Type | Amount added (% by mass) | Type | Amount added (% by mass) | Type | Amount added (% by mass) | | | | | |
| Example 4 | 2.5 | 2.5 | Hydrogen peroxide | 0.6 | Iron (III) nitrate | 0.1 | Malonic acid | 0.14 | 2.1 | 2.63 | 0.36 | Glossy | Perform polishing test immediately after preparation |
| Example 11 | | | | | | | | | 2.1 | 2.63 | 0.36 | Glossy | Perform polishing test 2 hours after preparing the polishing composition of Example 4 |
| Comparative Example 2 | 2.5 | 2.5 | Hydrogen peroxide | 0.6 | Iron (III) nitrate | 0.1 | Nitric acid | 0.08 | 1.6 | 1.75 | 0.34 | Glossy | A large amount of bubbles were generated immediately after the preparation. Perform polishing when bubbles are no longer generated. |
| Comparative Example 5 | | | | | | | | | 1.6 | 0.88 | 0.34 | Glossy | Perform polishing test 2 hours after the generation of bubbles immediately after preparation of the polishing composition of Comparative Example 2 subsided. |

As shown in the results of Table 3 above, Comparative Example 5 is the result of subjecting the polishing composition prepared in Comparative Example 2 to a polishing test 2 hours after the generation of bubbles after preparation subsided, and it is confirmed that the polishing rate is reduced by half as compared with Comparative Example 2 in which polishing was performed immediately after the generation of bubbles after preparation subsided. That is, it is shown that the storage stability is poor. On the other hand, Example 11 is the result of subjecting the polishing composition prepared in Example 4 to a polishing test 2 hours after the preparation and shows almost the same result of the polishing performance as the polishing composition of Example 4, and it is understood that the storage stability is excellent.

As shown in the results in Table 2 above, the polishing composition of Comparative Example 3 is an example in which acetic acid is used instead of the stabilizer used in the polishing compositions of Examples 1 to 4, which are the polishing compositions of the present invention. Although gloss was observed on the substrate surface after the polishing test, a plurality of scratches are visually confirmed, and the value of the surface roughness is also significantly deteriorated. In contrast, in Examples 1 to 4 satisfying the conditions of the polishing composition of the present invention, gloss was observed on the substrate surface after the polishing test, no scratch was visually confirmed, and the value of the surface roughness was remarkably improved as compared with Comparative Example 3.

As shown in the results in Table 2 above, the polishing composition of Comparative Example 4 is an example that does not contain an oxidation accelerator which is an essential constituent component in the polishing composition of the present invention, and the polishing rate was low, hazes were observed on the substrate surface after the polishing test, and a result of the surface roughness was remarkably reduced, relative to the polishing compositions of Examples 4 to 7 corresponding to the Comparative Example 4. In contrast, in Examples 4 to 7 having the requirements of the polishing composition of the present invention, the polishing rate was improved, gloss was observed on the substrate surface after the polishing test, and a good result of the surface roughness is shown.

The polishing composition of Example 8 is obtained by increasing the content (concentration) of colloidal silica relative to the configuration of the polishing composition of Example 4, the polishing composition of Example 9 is obtained by increasing the content (concentration) of hydrogen peroxide as an oxidizing agent relative to the configuration of the polishing composition of Example 4, and the polishing composition of Example 10 is obtained by increasing the content (concentration) of an oxidation accelerator relative to the configuration of the polishing composition of Example 4. The polishing compositions of Examples 8 to 10 all exhibit good polishing performance.

### (2) Polishing of InP Substrate

The polishing conditions for the polishing test of the polishing target using the polishing compositions prepared as Examples 12 and 13 and Comparative Examples 6 and 7 are as follows. The results of the polishing test under the polishing conditions are shown in Table 4 below.

### Polishing Conditions of InP Substrate

Polishing apparatus: One-side polishing machine having surface plate diameter of 360 mm
Polishing target: 2-inch InP substrate
Polishing pad: Nonwoven fabric SUBA800 (no groove)
Polishing pressure: 200 g/cm²
Surface plate rotating speed: 60 rpm
Polishing time: 20 min
Feed rate of polishing composition: Circulation, flow rate 200 ml/min

### Polishing Rate Ratio of InP Substrate

The weight of the 2-inch InP substrate which is a polishing target (hereinafter, simply referred to as “InP substrate”) was measured before and after the polishing test, and the polishing rate was calculated from the weight difference. The polishing rate ratio is shown as a relative value when the value of Comparative Example 6 is 1 (reference). The larger the value of the polishing rate ratio, the higher the polishing rate, and the higher the productivity.

### State of Substrate Surface of InP Substrate and Surface Roughness Sa of InP substrate

The state of the substrate surface and the surface roughness (Sa) of the substrate were measured in the same manner as a GaAs substrate.

TABLE 4

| Experiment number | Colloidal silica (% by mass) | | Oxidizing agent | | Oxidation accelerator | | Stabilizer | | pH (25° C.) | Polishing rate ratio (Comparative Example 6=1) | Sa (nm) | State of substrate surface | Remarks |
|---|---|---|---|---|---|---|---|---|---|---|---|---|---|
| | D50= 23 nm | D50= 110 nm | Type | Amount added (% by mass) | Type | Amount added (% by mass) | Type | Amount added (% by mass) | | | | | |
| Example 12 | 2.5 | 2.5 | Hydroge n peroxide | 0.6 | Iron (III) nitrate | 0.1 | Phosphoric acid | 0.13 | 2.1 | 5.09 | 0.78 | No scratches with white-light interference microscope | |
| Example 13 | 2.5 | 2.5 | Hydroge n peroxide | 0.6 | Iron (III) nitrate | 0.1 | Malonic acid | 0.14 | 2.1 | 3.24 | 0.57 | No scratches with white-light interference microscope | |
| Comparative Example 6 | 2.5 | 2.5 | Hydroge n peroxide | 0.6 | Iron (III) nitrate | 0.1 | - | - | 2.7 | 1 | 0.39 | 15 scratches out of 45 points with white-light interference microscope | Perform polishing test after the generation of bubbles immediately after preparation subsided. |
| Comparative Example 7 | 2.5 | 2.5 | Hydroge n peroxide | 0.6 | - | - | Malonic acid | 0.14 | 2.1 | 2.29 | 0.54 | 3 scratches out of 45 points with white-light interference microscope | |

### Consideration of InP Substrate

As shown in Table 4, the polishing composition of Comparative Example 6 does not contain a stabilizer, which is an essential constituent component of the polishing composition of the present invention. Therefore, although bubbles are generated immediately after the preparation of the polishing composition and it is difficult to handle the polishing composition in practical use, the above performance evaluation was performed on the polishing composition after the preparation. The polishing test itself was carried out after the generation of bubbles had subsided.

As shown in the results of Table 4 above, the value of the polishing rate in the polishing composition of Comparative Example 6 was less than or equal to half of Examples 12 and 13, and scratches were observed on the substrate surface in Comparative Example 6. In contrast, in Examples 12 and 13 satisfying the conditions of the polishing composition of the present invention, the polishing rate was high and no scratches were observed on the substrate surface.

As shown in the results of Table 4 above, the polishing composition of Comparative Example 7 is an example that does not contain an oxidation accelerator which is an essential constituent component in the polishing composition of the present invention, and the polishing rate was low and scratches were observed on the substrate surface, relative to the polishing compositions of Examples 12 and 13 corresponding to the Comparative Example 7. In contrast, in Examples 12 and 13 satisfying the conditions of the polishing composition of the present invention, the polishing rate was high and no scratches were observed on the substrate surface.

### (3) Polishing of GaP Substrate

The polishing conditions for the polishing test of the polishing target using the polishing compositions prepared as Examples 14 and 15 and Comparative Examples 8 and 9 are as follows. The results of the polishing test under the polishing conditions are shown in Table 5 below.

### Polishing Conditions of GaP Substrate

Polishing apparatus: One-side polishing machine having surface plate diameter of 360 mm
Polishing target: 2-inch GaP substrate
Polishing pad: Nonwoven fabric SUBA800 (no groove)
Polishing pressure: 200 g/cm²
Surface plate rotating speed: 60 rpm
Polishing time: 20 min
Feed rate of polishing composition: Circulation, flow rate 200 ml/min

### Polishing Rate Ratio of GaP Substrate

The weight of the 2-inch GaP substrate which is a polishing target (hereinafter, simply referred to as “GaP substrate”) was measured before and after the polishing test, and the polishing rate was calculated from the weight difference. The polishing rate ratio is shown as a relative value when the value of Comparative Example 8 is 1 (reference). The larger the value of the polishing rate ratio, the higher the polishing rate and the higher the productivity.

### State of Substrate Surface of GaP Substrate and Surface Roughness Sa of GaP substrate

The state of the substrate surface and the surface roughness (Sa) of the substrate were measured in the same manner as a GaAs substrate and an InP substrate.

TABLE 5

| Experiment number | Colloidal silica (% by mass) | | Oxidizing agent | | Oxidation accelerator | | Stabilizer | | pH (25° C.) | Polishing rate ratio (Comparative Example 8=1) | Sa (nm) | State of substrate surface | Remarks |
|---|---|---|---|---|---|---|---|---|---|---|---|---|---|
| | D50= 23 nm | D50= 110 nm | Type | Amount added (% by mass) | Type | Amount added (% by mass) | Type | Amount added (% by mass) | | | | | |
| Example 14 | 2.5 | 2.5 | Hydrogen peroxide | 0.6 | Iron (III) nitrat e | 0.1 | Phosphoric acid | 0.13 | 2.1 | 1.16 | 0.48 | No scratches with white-light interference microscope | |
| Example 15 | 2.5 | 2.5 | Hydrogen peroxide | 0.6 | Iron (III) nitrat e | 0.1 | Malonic acid | 0.14 | 2.1 | 1.30 | 0.44 | No scratches with white-light interference microscope | |
| Comparative Example 8 | 2.5 | 2.5 | Hydrogen peroxide | 0.6 | Iron (III) nitrat e | 0.1 | - | - | 2.7 | 1 | 0.64 | No scratches with white-light interference microscope | Perform polishing test after the generation of bubbles immediately after preparation subsided. |
| Comparative Example 9 | 2.5 | 2.5 | Hydrogen peroxide | 0.6 | - | - | Malonic acid | 0.14 | 2.1 | 1.12 | 0.52 | 2 scratches out of 45 points with white-light interference microscope | |

### Consideration of GaP Substrate

As shown in Table 5, the polishing composition of Comparative Example 8 does not contain a stabilizer, which is an essential constituent component of the polishing composition of the present invention. Therefore, although bubbles are generated immediately after the preparation of the polishing composition and it is difficult to handle the polishing composition in practical use, the above performance evaluation was performed on the polishing composition after the preparation. The polishing test itself was carried out after the generation of bubbles had subsided.

As shown in the results of Table 5 above, the polishing rate of the polishing composition of Comparative Example 8 was lower than that of Examples 14 and 15, and the surface roughness (Sa) was higher than that of Examples 14 and 15. In contrast, in Examples 14 and 15 satisfying the conditions of the polishing composition of the present invention, the polishing rate was high and the surface roughness was low.

As shown in the results of Table 5 above, the polishing composition of Comparative Example 9 is an example that does not contain an oxidation accelerator, which is an essential constituent component in the polishing composition of the present invention, and the polishing rate was low, the surface roughness was high, and scratches were observed on the substrate surface, relative to the polishing compositions of Examples 14 and 15 corresponding to the Comparative Example 9. In contrast, in Examples 14 and 15 satisfying the conditions of the polishing composition of the present invention, the polishing rate was high, the surface roughness was low, and no scratches were observed.

### (4) Polishing of GaN Substrate

The polishing conditions for the polishing test of the polishing target using the polishing composition prepared as Examples 16 and 17 and Comparative Examples 10 and 11 are as follows. The results of the polishing test under the polishing conditions are shown in Table 6 below.

### Polishing Conditions of GaN Substrate

Polishing apparatus: One-side polishing machine having surface plate diameter of 360 mm
Polishing target: 2-inch GaN substrate
Polishing pad: Nonwoven fabric SUBA800 (no groove)
Polishing pressure: 500 g/cm²
Surface plate rotating speed: 60 rpm
Polishing time: 120 min
Feed rate of polishing composition: Circulation, flow rate 200 ml/min

### Polishing Rate Ratio of GaN Substrate

The weight of the 2-inch GaN substrate which is a polishing target (hereinafter, simply referred to as “GaN substrate”) was measured before and after the polishing test, and the polishing rate was calculated from the weight difference. The polishing rate ratio is shown as a relative value when the value of Comparative Example 10 is 1 (reference). The larger the value of the polishing rate ratio, the higher the polishing rate and the higher the productivity.

### State of Substrate Surface of GaN Substrate and Surface Roughness Sa of GaN substrate

The state of the substrate surface and the surface roughness (Sa) of the substrate were measured in the same manner as a GaAs substrate, an InP substrate, and a GaP substrate.

TABLE 6

| Experiment number | Colloidal silica (% by mass) | | Oxidizing agent | | Oxidation accelerator | | Stabilizer | | pH (25° C.) | Polishing rate ratio (Comparative Example 10=1) | Sa (nm) | State of substrate surface | Remarks |
|---|---|---|---|---|---|---|---|---|---|---|---|---|---|
| | D50= 23 nm | D50= 110 nm | Type | Amount added (% by mass) | Type | Amount added (% by mass) | Type | Amount added (% by mass) | | | | | |
| Example 16 | 2.5 | 2.5 | Hydrogen peroxide | 0.6 | Iron (III) nitrate | 0.1 | Phosphoric acid | 0.13 | 2.1 | 1.37 | 0.36 | No scratches with white-light interference microscope | |
| Example 17 | 2.5 | 2.5 | Hydrogen peroxide | 0.6 | Iron (III) nitrate | 0.1 | Malonic acid | 0.14 | 2.1 | 1.59 | 0.31 | No scratches with white-light interference microscope | |
| Comparative Example 10 | 2.5 | 2.5 | Hydrogen peroxide | 0.6 | Iron (III) nitrate | 0.1 | - | - | 2.7 | 1 | 0.55 | No scratches with white-light interference microscope | Perform polishing test after the generation of bubbles immediately after preparation subsided. |
| Comparative Example 11 | 2.5 | 2.5 | Hydrogen peroxide | 0.6 | - | - | Malonic acid | 0.14 | 2.1 | 0.83 | 0.59 | No scratches with white-light interference microscope | |

### Consideration of GaN Substrate

As shown in Table 6, the polishing composition of Comparative Example 10 does not contain a stabilizer, which is an essential constituent component of the polishing composition of the present invention. Therefore, although bubbles are generated immediately after the preparation of the polishing composition and it is difficult to handle the polishing composition in practical use, the above performance evaluation was performed on the polishing composition after the preparation. The polishing test itself was carried out after the generation of bubbles had subsided.

As shown in the results of Table 6 above, the polishing rate of the polishing composition of Comparative Example 10 was lower than that of Examples 16 and 17, and the surface roughness (Sa) was higher than that of Examples 16 and 17. In contrast, in Examples 16 and 17 satisfying the conditions of the polishing composition of the present invention, the polishing rate was high and the surface roughness was low.

As shown in the results of Table 6 above, the polishing composition of Comparative Example 11 is an example that does not contain an oxidation accelerator which is an essential constituent component in the polishing composition of the present invention, and the polishing rate was low and the surface roughness was high, relative to the polishing compositions of Examples 16 and 17 corresponding to the Comparative Example 11. In contrast, in Examples 16 and 17 satisfying the conditions of the polishing composition of the present invention, the polishing rate was high and the surface roughness was low.

As described above, by using the polishing composition of the present invention and performing the polishing method using the polishing composition of the present invention, the storage stability of the polishing composition is improved, and stable polishing of the polishing target can be performed over a long period of time. Further, in the semiconductor wafer such as a GaAs wafer, an InP wafer, a GaP wafer, and a GaN wafer, it is possible to improve the polishing rate, improve the surface roughness of the substrate after polishing, and obtain a semiconductor in a good state with a glossy substrate surface.

### INDUSTRIAL APPLICABILITY

The polishing composition and the polishing method using the polishing composition of the present invention can be used for primary polishing or secondary polishing of electronic components employed in various electronic devices such as semiconductor devices and elements. In particular, the present invention can be suitably used for polishing a compound semiconductor wafer including a group III-V compound such as a GaAs wafer, an InP wafer, a GaP wafer, and a GaN wafer, as a constituent component.

1. A polishing composition for polishing a polishing target containing a group III-V compound as a constituent component, comprising:
colloidal silica,
an oxidizing agent,
an oxidation accelerator for accelerating an oxidation reaction on a surface of the polishing target by the oxidizing agent,
a stabilizer for controlling an accelerating action of the oxidation reaction on a surface of the polishing target by the oxidation accelerator, and
water.

2. The polishing composition according to claim 1, wherein the group III-V compound is at least one or more selected from the group consisting of gallium arsenide, gallium phosphide, indium phosphide, indium arsenide, aluminum arsenide, indium gallium arsenic compounds, indium gallium phosphorus compounds, aluminum gallium arsenic compounds, indium aluminum gallium arsenic compounds, gallium nitride, gallium antimony compounds, and indium antimony compounds.

3. The polishing composition according to claim 1, wherein the oxidizing agent is peroxide, permanganic acid or a salt thereof, chromic acid or a salt thereof, peroxo acid or a salt thereof, halogen oxo acid or a salt thereof, oxygen acid or a salt thereof, and a mixture thereof.

4. The polishing composition according to claim 1, wherein the oxidizing agent is hydrogen peroxide.

5. The polishing composition according to claim 1, wherein the oxidation accelerator is either an inorganic acid metal salt or an organic acid metal salt.

6. The polishing composition according to claim 5, wherein the inorganic acid metal salt is either iron nitrate or iron sulfate.

7. The polishing composition according to claim 1, wherein the stabilizer is at least one or more selected from the group consisting of phosphoric acid, phosphorous acid, organic phosphonic acid, polycarboxylic acid, and polyaminocarboxylic acid.

8. The polishing composition according to claim 7, wherein the polycarboxylic acid is either malonic acid or citric acid.

9. The polishing composition according to claim 1, wherein a pH value at 25° C. is in a range of 0.1 to 6.0.

10. A polishing method using the polishing composition according to claim 1 to polish a polishing target comprising a group III-V compound as a constituent component.
